(19) United States
(12) Patent Application Publication
(10) Pub. No.: US 2022/0408587 A1
(43) Pub. Date: Dec. 22, 2022

(54) SYSTEMS AND METHODS FOR IMMERSION-COOLED COMPUTERS

(71) Applicant: Microsoft Technology Licensing, LLC, Redmond, WA (US)

(72) Inventors: Douglas Patrick KELLEY, Sammamish, WA (US); Kathryn M. OSEEN-SENDA, Seattle, WA (US); Alexis Grace SCHUBERT, Seattle, WA (US); Dennis TRIEU, Calgary (CA)

(21) Appl. No.: 17/353,739

(22) Filed: Jun. 21, 2021

(51) Int. Cl. H05K 7/20; G06F 1/20

(52) U.S. Cl. CPC H05K 7/203; H05K 7/20327; H05K 7/20381; H05K 7/20809; G06F 1/206; G06F 2200/201

(57) ABSTRACT

An immersion cooling thermal management system includes a heat duct thermally coupled to a heat-generating electronic component. The heat duct has an inlet at a first longitudinal end of a channel and an outlet at an opposite second longitudinal end of the channel. The heat-generating electronic component is thermally coupled with the channel longitudinally between the inlet and the outlet. The outlet of the channel is higher than the inlet relative to a direction of gravity.

### BACKGROUND

### Background and Relevant Art

Computing devices can generate a large amount of heat during use. The computing components can be susceptible to damage from the heat and commonly require cooling systems to maintain the component temperatures in a safe range during heavy processing or usage loads. Liquid cooling can effectively cool components as liquid working fluids have more thermal mass than air or gas cooling. The liquid working fluid can be maintained at a lower temperature by allowing vaporized fluid to rise out of the liquid. The vapor in the cooling liquid can adversely affect the cooling performance of the working fluid. The vapor can be condensed and returned to the immersion tank.

### BRIEF SUMMARY

In some embodiments, an immersion cooling thermal management system includes a heat duct thermally coupled to a heat-generating electronic component. The heat duct has an inlet at a first longitudinal end of a channel and an outlet at an opposite second longitudinal end of the channel. The heat-generating electronic component is thermally coupled with the channel longitudinally between the inlet and the outlet. The outlet of the channel is higher than the inlet relative to a direction of gravity.

In some embodiments, a thermal management system includes an immersion chamber, a working fluid positioned in the immersion chamber, a heat-generating component, and a heat duct. The working fluid has a liquid phase and a vapor phase. The heat-generating component is positioned in the liquid phase of the working fluid and fixed to a substrate. The heat duct has an inlet at a first longitudinal end and an outlet at an opposite second longitudinal end. The heat duct is connected to and positioned on the substrate such that the heat-generating electronic component is located longitudinally between the inlet and the outlet to heat a portion of the liquid phase of the working fluid and induce a longitudinal flow of working fluid through the heat duct.

In some embodiments, a thermal management system includes an immersion chamber, a working fluid positioned in the immersion chamber, a first heat-generating electronic component, a second heat-generating electronic component, and a heat duct. The working fluid has a liquid phase and a vapor phase, and the vapor phase defines a headspace above the liquid phase. The first heat-generating component is positioned in the liquid phase of the working fluid and fixed to a substrate. The heat duct has an inlet at a first longitudinal end and an outlet at an opposite second longitudinal end. The heat duct is connected to and positioned on the substrate such that the first heat-generating electronic component is located longitudinally between the inlet and the outlet to heat a portion of the liquid phase of the working fluid and induce a longitudinal flow of working fluid through the heat duct. The second heat-generating component is positioned in the liquid phase of the working fluid and fixed to the substrate outside of the heat duct and proximate the inlet, such that the longitudinal flow of working fluid cools the second heat-generating electronic component.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the disclosure may be realized and obtained by means of the instruments and combinations particularly pointed out in the appended claims. Features of the present disclosure will become more fully apparent from the following description and appended claims or may be learned by the practice of the disclosure as set forth hereinafter.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a side schematic representation of an immersion cooling system;

FIG. 2 is a side schematic representation of an immersion cooling system with an external condenser, according to at least one embodiment of the present disclosure;

FIG. 3 is a perspective view of a server computer with a heat duct, according to at least one embodiment of the present disclosure;

FIG. 4 is a schematic representation of a thermal management system with columnar pressure differential, according to at least one embodiment of the present disclosure;

FIG. 5 is a schematic representation of a thermal management system with a plurality of heat ducts, according to at least one embodiment of the present disclosure;

FIG. 6-1 is a perspective view of a heat duct, according to at least one embodiment of the present disclosure;

FIG. 6-2 is a transverse cross-sectional view of the heat duct of FIG. 6-1;

FIG. 7 is a transverse cross-sectional view of a rounded heat duct, according to at least one embodiment of the present disclosure;

FIG. 8-1 is a transverse cross-sectional view of a finned heat duct, according to at least one embodiment of the present disclosure;

FIG. 8-2 is a side view of a fin of the heat duct of FIG. 8-1;

FIG. 9 is a transverse cross-sectional view of a heat duct with a vapor chamber, according to at least one embodiment of the present disclosure;

FIG. 10 is a transverse cross-sectional view of a heat duct with complementary thermal surface features, according to at least one embodiment of the present disclosure;

FIG. 11 is a schematic representation of a thermal management system with heat ducts, according to at least one embodiment of the present disclosure; and

FIG. 12 is a side view of a tilted heat duct and heat-generating electronic component, according to at least one embodiment of the present disclosure.

### DETAILED DESCRIPTION

The present disclosure relates generally to systems and methods for thermal management of electronic devices or other heat-generating components. Immersion chambers surround the heat-generating components in a liquid working fluid, which conducts heat from the heat-generating components to cool the heat-generating components. As the working fluid absorbs heat from the heat-generating components, the temperature of the working fluid increases. In some embodiments, the working fluid vaporizes, introducing vapor into the liquid of the working fluid.

In large-scale computing centers, such as cloud-computing centers, data processing centers, data storage centers, or other computing facilities, immersion cooling systems provide an efficient method of thermal management for many computing components under a variety of operating loads. In some embodiments, an immersion cooling system includes a working fluid in an immersion chamber and a condenser to extract heat from the vapor of the working fluid. The condenser then condenses the vapor phase of the working fluid into a liquid phase and returns the liquid working fluid to the immersion chamber. In some embodiments, the liquid working fluid absorbs heat from the heat-generating components, and one or more fluid conduits direct the hot liquid working fluid outside of the immersion chamber to a radiator or region of lower temperature to cool the liquid working fluid.

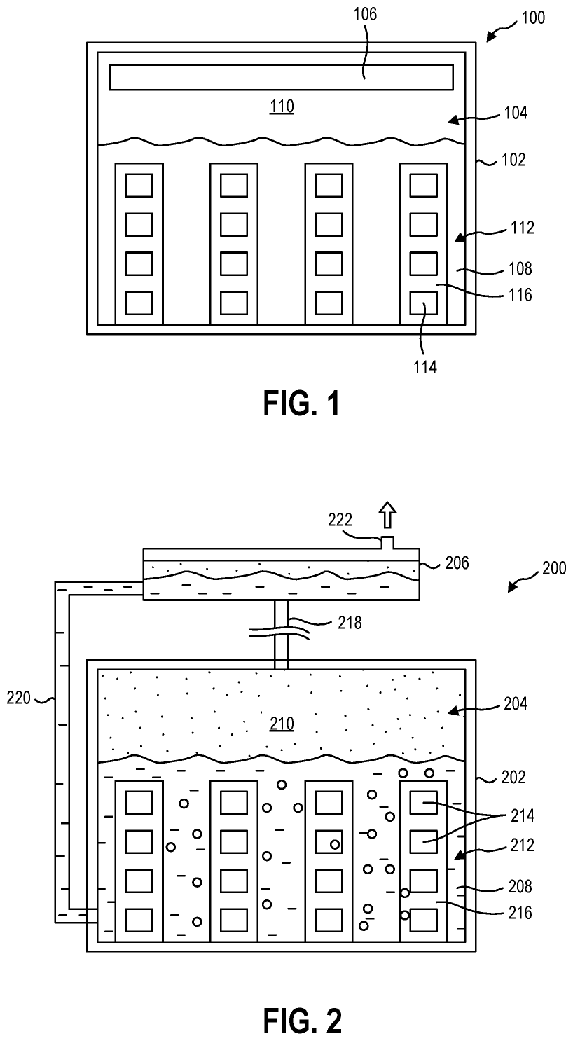

A conventional immersion cooling system 100, shown in FIG. 1, includes an immersion tank 102 containing an immersion chamber 104 and a condenser 106 in the immersion chamber 104. The immersion chamber 104 contains a working fluid that has a liquid working fluid 108 and a vapor working fluid 110 portion. The liquid working fluid 108 creates an immersion bath 112 in which a plurality of heat-generating components 114 are positioned to heat the liquid working fluid 108 on supports 116.

Referring now to FIG. 2, an immersion cooling system 200 according to the present disclosure includes an immersion tank 202 defining an immersion chamber 204 with a working fluid positioned therein. The working fluid transitions between a liquid working fluid 208 phase and a vapor working fluid 210 phase to remove heat from hot or heat-generating components 214 in the immersion chamber 204. The liquid working fluid 208 more efficiency receives heat from the heat-generating components 214 relative to a gaseous environment (e.g., vapor working fluid 210) and, upon transition to the vapor working fluid 210, the vapor working fluid 210 can be removed from the immersion tank 202, cooled and condensed by the condenser 206 to extract the heat from the working fluid, and the liquid working fluid 208 can be returned to the liquid immersion bath 212.

In some embodiments, the immersion bath 212 of the liquid working fluid 208 has a plurality of heat-generating components 214 positioned in the liquid working fluid 208. The liquid working fluid 208 surrounds at least a portion of the heat-generating components 214 and other objects or parts attached to the heat-generating components 214. In some embodiments, the heat-generating components 214 are positioned in the liquid working fluid 208 on one or more supports 216. The support 216 may support one or more heat-generating components 214 in the liquid working fluid 208 and allow the working fluid to move around the heat-generating components 214. In some embodiments, the support 216 is thermally conductive to conduct heat from the heat-generating components 214. The support(s) 216 may increase the effective surface area from which the liquid working fluid 208 may remove heat through convective cooling.

In some embodiments, the heat-generating components 214 include electronic or computing components or power supplies. In some embodiments, the heat-generating components 214 include computer devices, such as individual personal computer or server blade computers. In some embodiments, one or more of the heat-generating components 214 includes a heat sink or other device attached to the heat-generating component 214 to conduct away thermal energy and effectively increase the surface area of the heat-generating component 214. In some embodiments, the heat-generating components 214 include an electric motor.

As described, conversion of the liquid working fluid 208 to a vapor phase requires the input of thermal energy to overcome the latent heat of vaporization and may be an effective mechanism to increase the thermal capacity of the working fluid and remove heat from the heat-generating components. Because the vapor working fluid 210 rises in the liquid working fluid 208, the vapor working fluid 210 can be extracted from the immersion chamber 204 in a headspace of the chamber. A condenser 206 cools part of the vapor working fluid 210 back into a liquid working fluid 208, removing thermal energy from the system and reintroducing the working fluid into the immersion bath 212 of the liquid working fluid 208. The condenser 206 radiates or otherwise dumps the thermal energy from the working fluid into the ambient environment or into a conduit to carry the thermal energy away from the cooling system.

In conventional immersion cooling systems, a liquid-cooled condenser is integrated into the immersion tank and/or the chamber to efficiently remove the thermal energy from the working fluid. In some embodiments according to the present disclosure, an immersion cooling system 200 for thermal management of computing devices allows at least one immersion tank 202 and/or chamber 204 to be connected to and in fluid communication with an external condenser 206. In some embodiments, an immersion cooling system includes a vapor return line 218 that connects the immersion tank 202 to the condenser 206 and allows vapor working fluid 210 to enter the condenser 206 from the immersion tank 202 and/or chamber 204 and a liquid return line 220 that connects the immersion tank 202 to the condenser 206 and allows liquid working fluid 208 to return to the immersion tank 202 and/or chamber 204.

The vapor return line 218 may be colder than the boiling temperature of the working fluid. In some embodiments, a portion of the vapor working fluid condenses in the vapor return line 218. The vapor return line 218 can, in some embodiments, be oriented at an angle such that the vapor return line 218 is non-perpendicular to the direction of gravity. The condensed working fluid can then drain either back to the immersion tank 202 or forward to the condenser 206 depending on the direction of the vapor return line 218 slope. In some embodiments, the vapor return line 218 includes a liquid collection line or valve, like a bleeder valve, that allows the collection and/or return of the condensed working fluid to the immersion tank 202 or condenser 206. In some examples, an immersion cooling system 200 includes an air-cooled condenser 206. An air-cooled condenser 206 may require fans or pumps to force ambient air over one or more heat pipes or fins to conduct heat from the condenser to the air.

In some embodiments, the movement of the vapor bubbles through the liquid working fluid can induce a flow of the liquid working fluid through fluidic drag and/or relative columnar pressure in the liquid working fluid in the immersion chamber. The liquid working fluid convectively cools the heat-generating components more efficiently when the liquid working fluid flows over the heat-generating components compared to thermal transfer to a static liquid working fluid. For example, flowing liquid working fluid provides a thinner boundary layer, and forced convection will more effectively evacuate vapor bubbles and prevent film boiling. In embodiments with subcooled liquid working fluid (e.g., cooled below the boiling temperature), such as subcooled condensate in a liquid return line, the liquid working fluid can provide even greater cooling capacity.

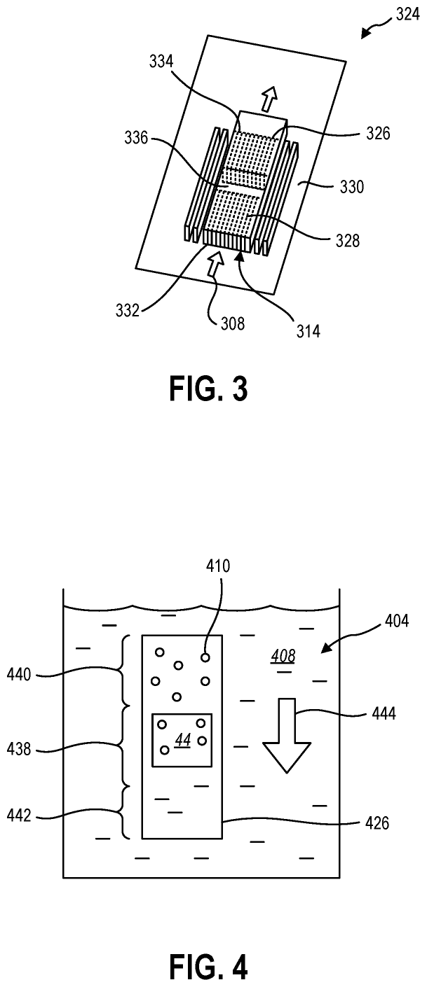

FIG. 3 is a perspective view of a server computer 324 with a heat duct 326 to cool a heat-generating electronic component 314 of the server computer 324. In some embodiments, the heat duct 326 is thermally coupled with the heat-generating electronic component 314 to induce a flow of liquid working fluid 308 past a heat sink 328 of the heat-generating electronic component 314. The heat-generating electronic component 314, such as a central processing unit (CPU), a graphical processing unit (GPU), a networking device, a power supply, or another relatively high-power electronic component is thermally coupled with a heat sink 328 to remove the heat from the heat-generating electronic component 314 as it is generated during operation.

In some embodiments, the heat duct 326 is thermally coupled to the heat-generating electronic component 314. For example, the heat duct 326 may be contacting the heat-generating electronic component 314. In some examples, the heat duct 326 may be thermally coupled to the heat-generating electronic component 314 by a thermal paste positioned between the heat duct 326 and the heat-generating electronic component 314. In some examples, the heat duct 326 may be thermally coupled to the heat-generating electronic component 314 by a liquid phase metal positioned between the heat duct 326 and the heat-generating electronic component 314. In some examples, the heat duct 326 may be thermally coupled to the heat-generating electronic component 314 by a heat spreader positioned between the heat duct 326 and the heat-generating electronic component 314. In some embodiments, the heat duct 326 may be thermally coupled to the heat-generating electronic component 314 by a heat sink 328 positioned between and contacting the heat duct 326 and the heat-generating electronic component 314.

In some embodiments, the heat sink 328 is fixed to the heat-generating electronic component 314, and the heat duct 326 is fixed to a substrate 330 (such as a motherboard) of the server computer 324 or other computing device to position the heat duct 326 around the heat-generating electronic component 314 and heat sink 328. In some embodiments, the heat sink 328 is integrated with and/or part of the heat duct 326, such that the heat sink 328 and heat duct 326 are fixed to the heat-generating electronic component 314.

In some embodiments, the computing device includes a plurality of heat-generating electronic components 314 and less than all of the plurality of heat-generating electronic components is thermally coupled the heat duct 326. For example, the heat duct 326 may be positioned on the computing device to direct fluid flow over and/or past the CPU and the GPU. In some embodiments, only one heat-generating electronic component 314 or type of heat-generating electronic component of the computing device is thermally coupled with the heat duct 326. For example, the heat duct 326 may be positioned on the computing device to direct fluid flow over and/or past the CPU(s) only.

The heat duct 326 has an inlet 332 located at a first longitudinal end of the heat duct 326 and an outlet 334 located at a second longitudinal end of the heat duct 326. A channel 336 in the longitudinal direction connects the inlet 332 and the outlet 334 to allow working fluid to flow through the heat duct 326 and exhaust heat from the heat-generating electronic component 314. In some embodiments, the heat duct 326 has a constant cross-sectional area in the longitudinal direction. In some embodiments, the heat duct 326 varies in cross-sectional area in the longitudinal direction. For example, the heat duct 326 may increase in cross-sectional area toward the outlet 334 to accommodate the increase in volume of the working fluid therein as the working fluid boils. For example, the heat duct 326 may decrease in cross-sectional area or taper toward the outlet 334 to accelerate the flow of the working fluid therein as the working fluid boils.

FIG. 4 is a schematic representation of an immersion chamber 404 with a heat-generating electronic component 414 thermally coupled with a heat duct 426. As the heat-generating electronic component 414 heats the liquid working fluid 408 in a cooling volume 438, the liquid working fluid 408 may boil. When the liquid working fluid 408 boils and converts into bubbles of vapor working fluid 410, the density of the column of working fluid in the cooling volume 438 (and above the cooling volume) decreases. For example, the liquid working fluid 408 may be approximately 100 times or more denser than the vapor working fluid 410. The heat duct 426 confines the movement of working fluid in the cooling volume 438 and allows only substantially vertical movement of the working fluid. In an example where the liquid working fluid 408 is 100 times denser than the vapor working fluid 410, boiling a portion of the liquid working fluid 408 to change the cooling volume 438 to 50% liquid working fluid 408 and 50% vapor working fluid 410 decreases the density of the cooling volume 438 by 49.5%.

The bubbles of vapor working fluid 410 rise into the bubble volume 440 above the heat-generating electronic component 414. In some embodiments, the path of the bubbles is confined by the heat duct 426. The cooling volume 438 around the heat-generating electronic component 414 and the bubble volume 440 above the heat-generating electronic component 414 containing the bubbles is less dense than the liquid volume 442 below the heat-generating electronic component. The columnar pressure 444 of the liquid working fluid 408 surrounding the heat duct 426 applies a pressure to the fluid in the heat duct 426 to move the fluid in a longitudinal direction in the heat duct 426. The relative columnar pressure 444 of the liquid working fluid 408 outside of the heat duct 426 to the mixed liquid working fluid 408 and vapor working fluid 410 inside of the heat duct 426 produces a net force on the working fluid in the heat duct 426. As the heat-generating electronic component 414 heats up and boils the liquid working fluid 408 in the heat duct 426, the proportion of the vapor working fluid 410 in the heat duct 426 increases, which causes the net force on the working fluid in the heat duct 426 to increase, further accelerating the working fluid in the heat duct 426 to increase fluid flow and cooling capacity. In this manner, the heat duct operates as a thermosiphon that accelerates fluid flow and increases cooling based at least partially upon the amount of heat generated by the heat-generating electronic component 414.

To maintain the relative columnar pressure 444, the heat-generating electronic component 414 may boil the liquid working fluid rapidly. For example, the heat-generating electronic component 414 may have a peak operating power of at least 400 Watts. In other examples, the heat-generating electronic component 414 may have a peak operating power of at least 600 Watts. In other examples, the heat-generating electronic component 414 may have a peak operating power of at least 800 Watts. In other examples, the heat-generating electronic component 414 may have a peak operating power of at least 1000 Watts.

In some embodiments, an operating temperature of the heat-generating electronic component 414 may be at least 0.10° Celsius (C) above a boiling temperature of the working fluid. For example, the operating temperature of the heat-generating electronic component may be 60.1° C. and the boiling temperature of the working fluid may be 60° C. In some embodiments, an operating temperature of the heat-generating electronic component 414 may be at least 1.0° C. above a boiling temperature of the working fluid. In some embodiments, an operating temperature of the heat-generating electronic component 414 may be at least 10° C. above a boiling temperature of the working fluid. In some embodiments, an operating temperature of the heat-generating electronic component 414 may be at least 15° C. above a boiling temperature of the working fluid. In some embodiments, an operating temperature of the heat-generating electronic component 414 may be at least 20° C. above a boiling temperature of the working fluid.

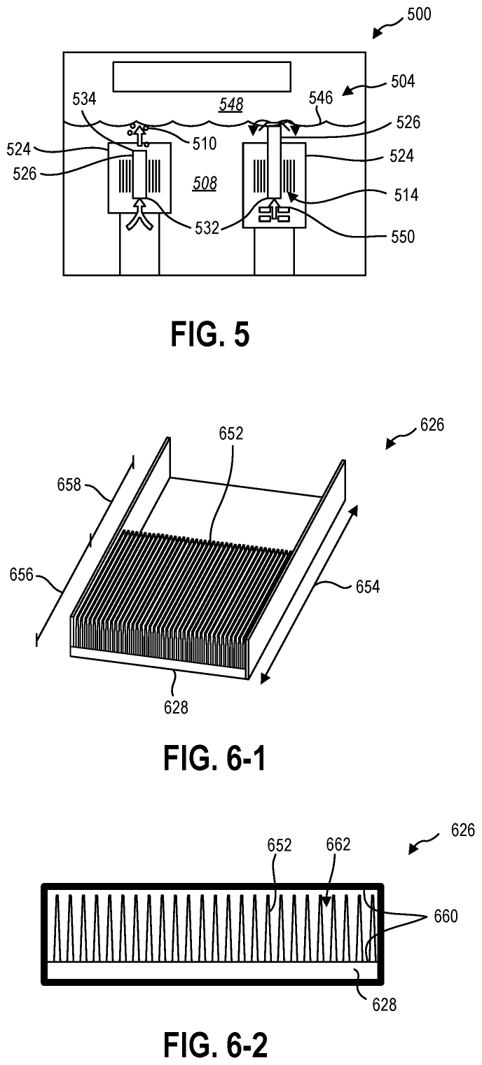

Referring now to FIG. 5, in some embodiments, a thermal management system 500 includes server computers 524 or other computing devices with heat ducts 526 fixed thereto. As described herein, in some embodiments, the heat ducts 526 are fixed to the motherboard or other substrate 530 of the computing device. In some embodiments, the heat ducts 526 are integrated into a heat sink that is fixed to the heat-generating electronic component 514. The heat from the heat-generating electronic component 514 may boil a portion of the liquid working fluid 508 in the heat duct 526 to accelerate working fluid through the heat duct 526. The net force is at least partially based upon the relative columnar pressure.

In some embodiments, the vapor bubbles of vapor working fluid 510 are allowed to disperse in the liquid working fluid 508 after exiting the outlet 534 of the heat duct 526. In some embodiments, the heat duct 526 extends to the liquid level 546 of the liquid working fluid 508 to confine the vapor bubbles in the heat duct 526. By limiting and/or preventing the movement of the vapor bubbles out of the heat duct 526 until entering the headspace 548 of the immersion chamber 504, the density of the working fluid in the heat duct 526 is minimized. With all vapor bubbles created by the boiling of the liquid working fluid 508 by the heat-generating electronic component 514 confined in the heat duct, the relative columnar pressure is maximized. The fluid flow is, therefore, increased.

The heat duct 526 may accelerate the working fluid therethrough by lowering the density of the working fluid in the heat duct 526. The fluid flow can increase the cooling capacity by flowing cooler liquid working fluid 508 toward the heat-generating electronic component 514 from the immersion bath. In some embodiments, secondary heat-generating electronic components 550 of the server computer 524 or other computing device receive additional cooling from the flow of liquid working fluid 508 drawn into the inlet 532 of the heat duct.

A secondary heat-generating electronic component 550 may be positioned on the server computer 524 or other computing device (e.g., on the same motherboard or other substrate) below the heat duct 526 and/or proximate the heat duct inlet 532. The heat duct 526 draws liquid working fluid 508 into the inlet 532, and the induced flow of liquid working fluid 508 proximate the inlet 532 can cool the secondary heat-generating electronic component 550 proximate the inlet 532.

FIG. 6-1 and FIG. 6-2 are a perspective view and an transverse cross-sectional view, respectively, of an embodiment of a heat duct 626 with integrated heat sink 628. FIG. 6-1 illustrates the embodiment of a heat duct 626 with the top surface of the heat duct removed. A heat duct 626 may be placed around or integrated with a heat sink 628. In some embodiments, the heat sink 628 includes one or more thermal surface features to dissipate heat from the heat-generating electronic component into the working fluid inside the heat duct 626. The thermal surface features may include fins 652, rods, heat pipes, vapor chambers, mesh, sponge, surface textures, or any other features that increase the surface area and/or thermal transfer rate of the heat sink 628 and/or heat duct 626.

In some embodiments, the thermal surface features are located in the heat sink 628 and/or heat duct 626 to longitudinally overlap the heat-generating electronic component. For example, the heat duct 626 may be longer in a longitudinal direction 654 than the heat-generating electronic component, such as a processor. The thermal surface features (e.g., fins 652) may be located only in the first longitudinal portion 656 of the heat sink and/or heat duct where the heat-generating electronic component is located to receive and transfer heat from the heat-generating electronic component. The heat duct 626 may lack thermal surface features or have less or smaller thermal surface features in a second longitudinal portion(s) 658 of the heat duct 626 that does not contact or overlap the heat-generating electronic component. Eliminating or reducing the thermal surface features from the second longitudinal portion(s) 658 of the heat duct 626 that does not contact or overlap the heat-generating electronic component can reduce drag on the working fluid and allow for faster fluid flow through the heat duct 626.

Referring now to FIG. 6-2, the thermal surface features, in some embodiments, project from an inner surface 660 of the heat duct 626 into interior area 662 of the heat duct 626 to transfer heat to the working fluid therein. The thermal surface features may not contact the opposite inner surface (e.g., opposite the heat sink 628 in FIG. 6-2) and create a plurality of channels in the heat duct 626. Having a plurality of enclosed channels impedes liquid fluid flow and can increase the risk of dry out in the heat duct.

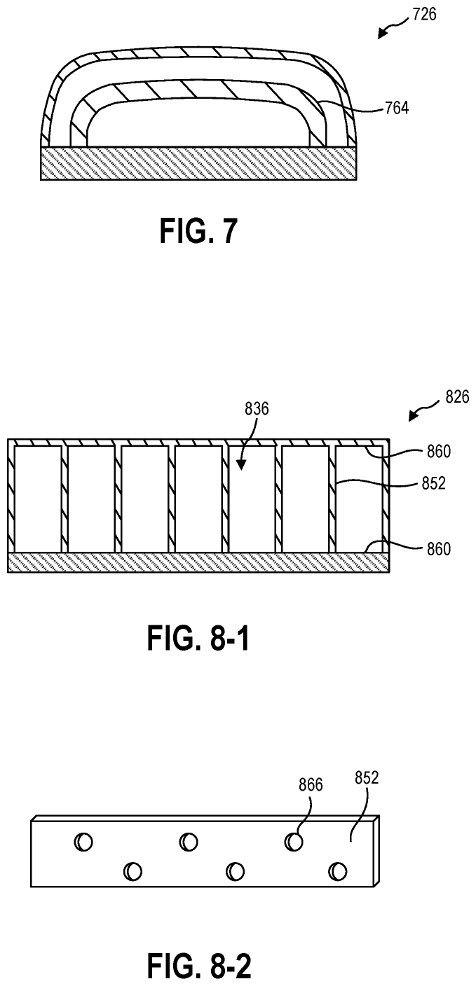

The heat duct may have any of a variety of cross-sectional shapes (e.g., perpendicular to the longitudinal direction). In some embodiments, the heat duct has a cross-sectional shape that is rectangular, square, triangular, pentagonal, hexagonal, other regular polygonal, curved, round, oval, irregular, or combination thereof. For example, the heat duct may have a cross-sectional shape that is at least partially related to the shape of one or more thermal surface features. FIG. 7 is a transverse cross-sectional view of another embodiment of a heat duct 726, according to the present disclosure. In at least one embodiment, the thermal surface feature is a conductive rod 764 (or longitudinal series of rods) that forms an arc fixed to a heat sink, while the heat duct 726 has a cross-sectional shape that is rounded to complementarily follow the curve of the arc.

FIG. 8-1 is a transverse cross-sectional view of another embodiment of a heat duct 826, according to the present disclosure. In at least one embodiment, the thermal surface features (e.g., fins 852 contact both a first side of the inner surface 860 and an opposite second side of the inner surface 862. In such embodiments, the thermal surface features, such as fins, can create isolated channels 836 that inhibit fluid flow in a transverse direction and risk dry out. As illustrated in the side view of a fin 852 in FIG. 8-2, in some embodiments, the thermal surface features may have apertures 866 therein to allow the transverse movement of liquid working fluid through the channel of the heat duct.

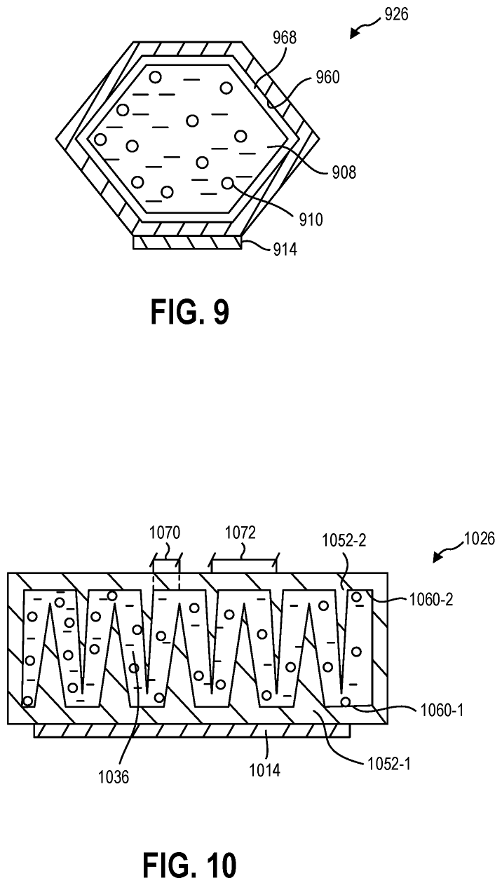

The heat duct may include one or more thermal surface features to promote boiling of the liquid working fluid from more than one side of the inner surface. In some embodiments, such as that shown in transverse cross-section in FIG. 9, a vapor chamber 968 is positioned on the inner surface 960 of the heat duct 926 to transfer and/or spread heat from the heat-generating electronic component 914. The vapor chamber 968 transfers heat from the heat-generating electronic component 914 across at least a portion of the inner surface 960 to evenly heat the liquid working fluid 908 and boil the liquid working fluid 908. In some embodiments, the thermal surface features are positioned on the side of the inner surface 960 opposite the heat-generating electronic component 914, such that the increased surface area of the thermal surface features results in even heating of the liquid working fluid 908 from the hotter side proximate the heat-generating electronic component 914 and the cooler side opposite the heat-generating electronic component 914 with the thermal surface features. In at least one embodiment, such as illustrated in FIG. 9, the thermal surface feature (e.g., the vapor chamber 968) is located on all of the inner surface at at least one longitudinal position in the heat duct. For example, the entire inner surface 960 of the heat duct 926 may be a vapor chamber 968. In some examples, the vapor chamber 968 is located longitudinally in the longitudinal portion of heat duct 926 where the heat-generating electronic component 914 is located (e.g., the first longitudinal portion 656 of FIG. 6-1), and the vapor chamber 968 wraps around the inner surface 960 before terminating after the longitudinal portion of heat duct 926 where the heat-generating electronic component 914 is located (e.g., not located in the second longitudinal portion 658 of FIG. 6-1).

Even heating of the liquid working fluid 908 may promote vaporization of the liquid working fluid 908 equally, causing entrainment of the liquid working fluid 908 with the vapor bubbles of the vapor working fluid 910. Because the movement of (and lower density of) the vapor working fluid 910 in the heat duct 926 establishes the flow through the heat duct 926, a counter flow of liquid working fluid 908 down the heat duct 926 will adversely impact the cooling capacity of the thermal management system. In some embodiments, the heat duct 926 has enough cross-sectional area to allow fluid flow and prevent dry out while not having too much cross-sectional area to allow counter flow of the liquid working fluid 908. While promotion of vapor working fluid 910 throughout the cross-sectional area can help prevent counter flow, complementary surface features can also limit the open cross-sectional area of the heat duct 926 and promote entrainment.

For example, FIG. 10 is a transverse cross-sectional view of an embodiment of a heat duct 1026 with complementary thermal surface features 1052-1, 1052-2. In some embodiments, a heat duct 1026 has first thermal surface features 1052-1 on a bottom side 1060-1 (proximate the heat-generating electronic component 1014) of the inner surface and second thermal surface features 1052-2 on the top side 1060-2 of the inner surface. The thermal surface features 1052-1, 1052-2 on opposite or adjacent sides of the inner surface may be complementary to one another to maintain a substantially constant gap 1070 for a channel 1036 between the first thermal surface features 1052-1 on the bottom side 1060-1 of the inner surface and the second thermal surface features 1052-2 on the top side 1060-2 of the inner surface. For example, fins protruding from a top side 1060-2 of the inner surface may be positioned in the spacing 1072 between fins protruding from a bottom side 1060-1 of the inner surface. By having the first thermal surface elements 1052-1 and the second thermal surface features 1052-2 have the same spacing 1072, a constant gap 1070 may be maintained.

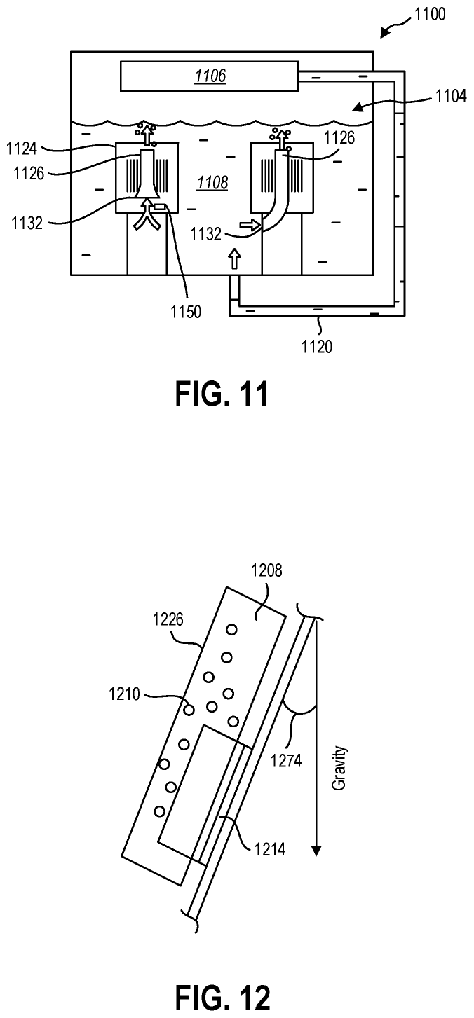

Referring now to FIG. 11, some thermal management systems 1100, according to the present disclosure, use the change in working fluid density upon boiling to create pressure differentials in the immersion chamber 1104. In some embodiments, a thermal management system 1100 uses the pressure differential in the immersion chamber 1104 to direct or draw liquid working fluid 1108 from a particular area or volume of the immersion chamber 1104. For example, a shape of the inlet 1132 of the heat duct 1126 may be selected to draw liquid working fluid 1108 across one or more secondary heat-generating electronic components, as describe herein. For example, a flared or wide inlet 1132 may draw liquid working fluid 1108 from a larger area across the server computer 1124 or other computing device to actively force liquid flow over the secondary heat-generating electronic components 1150. In another example, a flared or wide inlet 1132 may draw liquid working fluid 1108 into the heat duct 1126, which subsequently narrows in the direction of flow, to accelerate the fluid via the Venturi effect to increase cooling capacity.

In some embodiments, the inlet 1132 of a heat duct 1126 is located in the immersion chamber 1104 to draw liquid working fluid 1108 from a particular location in the immersion chamber 1104. For example, the inlet 1132 may be directed toward a region of the immersion chamber 1104 away from the secondary heat-generating electronic components 1150 of the server computer or any other heat-generating electronic components in the immersion chamber 1104 to draw in cooler liquid working fluid 1108. In at least one example, the inlet 1132 of the heat duct 1126 is located proximate an outlet of a liquid return line 1120. The returning liquid working fluid 1108 (e.g., returning from the condenser 1106) may be subcooled below the temperature of the liquid working fluid 1108 in the immersion chamber 1104. The liquid working fluid 1108 located in the region with the coolest liquid working fluid will provide more efficient cooling to the heat-generating electronic component connected to and/or in thermal conductivity with the heat duct 1126.

While embodiments of thermal management systems have been described with the heat duct oriented generally vertically relative to gravity to allow the vapor bubbles to rise, in some embodiments, at least a portion of the heat duct and heat-generating electronic component may be angled relative to gravity to allow the vapor bubbles to rise away from the heat-generating electronic component in the heat duct.

FIG. 12 illustrates an embodiment of a server computer motherboard or other substrate 1230 that is tilted relative to gravity to position at least a portion of the heat duct 1226 vertically above the heat-generating electronic component 1214. As the heat-generating electronic component 1214 boils the liquid working fluid 1208 in the heat duct 1226, the vapor working fluid 1210 will rise in the direction of gravity and away from the surface of the heat-generating electronic component 1214. While this can limit and/or prevent dry out of the component, too large of a tilt angle 1274 relative to the direction of gravity can induce a counter flow of liquid working fluid 1208 and limit and/or prevent entrainment. In some embodiments, the tilt angle 1274 of the heat duct 1226 and/or heat-generating electronic component 1214 relative to gravity is between 0° and 10°. In some embodiments, the tilt angle 1274 of the heat duct 1226 and/or heat-generating electronic component 1214 relative to gravity is less than 5°. In some embodiments, the tilt angle 1274 of the heat duct 1226 and/or heat-generating electronic component 1214 relative to gravity is less than 2.5°.

### INDUSTRIAL APPLICABILITY

The present disclosure relates generally to systems and methods for thermal management of electronic devices or other heat-generating components. Immersion chambers surround or partially surround the heat-generating components in a liquid working fluid, which conducts heat from the heat-generating components to cool the heat-generating components. As the working fluid absorbs heat from the heat-generating components, the temperature of the working fluid increases and the working fluid may vaporize, introducing vapor into the liquid of the working fluid. The vapor will rise due to buoyancy in the opposite direction of gravity, rising out of the liquid working fluid and entering a headspace above the liquid working fluid.

An immersion cooling system according to the present disclosure includes an immersion chamber with a working fluid positioned therein. The working fluid transitions between a liquid phase and a vapor phase to remove heat from hot or heat-generating components in the chamber. The liquid phase more efficiency receives heat from the components and, upon transition to the vapor phase, the working fluid can be cooled and condensed to extract the heat from the working fluid before the working fluid is returned to the liquid immersion bath at a lower temperature.

In some embodiments, the immersion bath of the liquid working fluid has a plurality of heat-generating components positioned in the liquid working fluid. The liquid working fluid surrounds the heat-generating components and other objects or parts attached to the heat-generating components. In some embodiments, the heat-generating components are positioned in the liquid working fluid on one or more supports. In some examples, the support is a motherboard of a computing device. The support may support one or more heat-generating components in the liquid working fluid and allow the working fluid to move around the heat-generating components. In some embodiments, the support is thermally conductive to conduct heat from the heat-generating components. The support(s) may increase the effective surface area from which the working fluid may remove heat through convective cooling. In some embodiments, one or more of the heat-generating components includes a heat sink or other device attached to the heat-generating component to conduct away thermal energy and effectively increase the surface area of the heat-generating component.

As described, conversion of the liquid working fluid to a vapor phase requires the input of thermal energy to overcome the latent heat of vaporization and may be an effective mechanism to increase the thermal capacity of the working fluid and remove heat from the heat-generating components. Because the vapor rises in the liquid working fluid, the vapor phase of the working fluid accumulates in an upper vapor region of the chamber. Conventionally, a condenser cools part of the vapor of the working fluid back into a liquid phase, removing thermal energy from the system and reintroducing the working fluid into the immersion bath of the liquid working fluid. The condenser radiates or otherwise dumps the thermal energy from the working fluid into the ambient environment or into a conduit to carry the thermal energy away from the cooling system.

In some embodiments, the movement of the vapor bubbles through the liquid working fluid can induce a flow of the liquid working fluid through fluidic drag and/or relative columnar pressure in the liquid working fluid in the immersion chamber. In some embodiments, the liquid working fluid receives heat in a cooling volume of working fluid immediately surrounding the heat-generating components. The cooling volume is the region of the working fluid (including both liquid and vapor phases) that is immediately surrounding the heat-generating components and is responsible for the convective cooling of the heat-generating components. In some embodiments, the cooling volume is the volume of working fluid within 5 millimeters (mm) of the heat-generating components.

The working fluid has a boiling temperature below a threshold temperature at which the heat-generating components experience thermal damage. For example, the heat-generating components may be computing components that experience damage above 100° Celsius (C). In some embodiments, the boiling temperature of the working fluid is less than a threshold temperature of the heat-generating components. In some embodiments, the boiling temperature of the working fluid is less about 90° C. In some embodiments, the boiling temperature of the working fluid is less about 80° C. In some embodiments, the boiling temperature of the working fluid is less about 70° C. In some embodiments, the boiling temperature of the working fluid is less about 60° C. In some embodiments, the boiling temperature of the working fluid is at least about 35° C. In some embodiments, the working fluid includes water. In some embodiments, the working fluid includes glycol. In some embodiments, the working fluid includes a combination of water and glycol. In some embodiments, the working fluid is an aqueous solution. In some embodiments, the working fluid is an electronic liquid, such as FC-72 or FC-3284 available from 3M, or similar non-conductive fluids. In some embodiments, the working fluid is a hydrocarbon or alcohol. In some embodiments, the heat-generating components, supports, or other elements of the immersion cooling system positioned in the working fluid have nucleation sites on a surface thereof that promote the nucleation of vapor bubbles of the working fluid at or below the boiling temperature of the working fluid.

In some embodiments, a thermal management system includes a heat duct thermally coupled with a heat-generating electronic component to induce a flow of liquid working fluid past a heat sink of the heat-generating electronic component. The heat-generating electronic component, such as a central processing unit (CPU), a graphical processing unit (GPU), a networking device, a power supply, or another relatively high-power electronic component is thermally coupled with a heat sink to remove the heat from the heat-generating electronic component as it is generated.

In some embodiments, the heat sink is fixed to the heat-generating electronic component, and the heat duct is fixed to a substrate (such as a motherboard) of the computing device to position the heat duct around the heat-generating electronic component and heat sink. In some embodiments, the heat sink is integrated with and/or part of the heat duct, such that the heat sink and heat duct are fixed to the heat-generating electronic component.

In some embodiments, the computing device includes a plurality of heat-generating electronic components and less than all of the plurality of heat-generating electronic components is thermally coupled with the heat duct. For example, the heat duct may be positioned on the computing device to direct fluid flow over and/or past the CPU and the GPU. In some embodiments, only one heat-generating electronic component or type of heat-generating electronic component of the computing device is thermally coupled with the heat duct. For example, the heat duct may be positioned on the computing device to direct fluid flow over and/or past the CPU(s) only.

The heat duct has an inlet located at a first longitudinal end of the heat duct and an outlet located at a second longitudinal end of the heat duct. A channel in the longitudinal direction connects the inlet and the outlet to allow working fluid to flow through the heat duct and exhaust heat from the heat-generating electronic component. In some embodiments, the heat duct has a constant cross-sectional area in the longitudinal direction. In some embodiments, the heat duct varies in cross-sectional area in the longitudinal direction. For example, the heat duct may increase in cross-sectional area toward the outlet to accommodate the increase in volume of the working fluid therein as the working fluid boils. For example, the heat duct may decrease in cross-sectional area toward the outlet to accelerate the flow of the working fluid therein as the working fluid boils.

As the heat-generating electronic component heats the liquid working fluid in the cooling volume, the liquid working fluid may boil. When the liquid working fluid boils and converts into bubbles of vapor working fluid, the density of the column of working fluid in the cooling volume (and above the cooling volume) decreases. For example, the liquid working fluid may be approximately 100 times or more denser than the vapor working fluid. The heat duct confines the movement of working fluid in the cooling volume and allows only substantially vertical movement of the working fluid and isolates the two-phase working fluid in the heat duct from the static pressure of the liquid working fluid outside of the heat duct. In an example where the liquid working fluid is 100 times denser than the vapor working fluid, boiling a portion of the liquid working fluid to change the cooling volume to 50% liquid working fluid and 50% vapor working fluid decreases the density of the cooling volume by 49.5%.

The bubbles of vapor working fluid rise into the bubble volume above the heat-generating electronic component. In some embodiments, the path of the bubbles is confined by the heat duct. The cooling volume around the heat-generating electronic component and the bubble volume above the heat-generating electronic component containing the bubbles is less dense than the liquid volume below the heat-generating electronic component. The columnar pressure of the liquid working fluid surrounding the heat duct applies a pressure to the fluid in the heat duct to move the fluid in a longitudinal direction in the heat duct. The relative columnar pressure of the liquid working fluid outside of the heat duct to the mixed liquid working fluid and vapor working fluid inside of the heat duct produces a net force on the working fluid in the heat duct. As the heat-generating electronic component heats up and boils the working fluid in the heat duct, the proportion of the vapor working fluid in the heat duct increases, which causes the net force on the working fluid in the heat duct to increase, further accelerating the working fluid in the heat duct to increase fluid flow and cooling capacity. In this manner, the heat duct operates as a thermosiphon that accelerates fluid flow and increases cooling based at least partially upon the amount of heat generated by the heat-generating electronic component.

To maintain the relative columnar pressure, the heat-generating electronic component may boil the liquid working fluid rapidly. For example, the heat-generating electronic component may have a peak operating power of at least 400 Watts. In other examples, the heat-generating electronic component may have a peak operating power of at least 600 Watts. In other examples, the heat-generating electronic component may have a peak operating power of at least 800 Watts. In other examples, the heat-generating electronic component may have a peak operating power of at least 1000 Watts.

In some embodiments, an operating temperature of the heat-generating electronic component may be at least 10° Celsius (C) above a boiling temperature of the working fluid. For example, the operating temperature of the heat-generating electronic component may be 60° C. and the boiling temperature of the working fluid may be 50° C. In some embodiments, an operating temperature of the heat-generating electronic component may be at least 15° C. above a boiling temperature of the working fluid. In some embodiments, an operating temperature of the heat-generating electronic component may be at least 20° C. above a boiling temperature of the working fluid.

In some embodiments, a thermal management system includes server computers or other computing devices with heat ducts fixed thereto. As described herein, in some embodiments, the heat ducts are fixed to the motherboard or other substrate of the computing device. In some embodiments, the heat ducts are integrated into a heat sink that is fixed to the heat-generating electronic component. The heat from the heat-generating electronic component may boil a portion of the liquid working fluid in the heat duct to accelerate working fluid through the heat duct. The net force is at least partially based upon the relative columnar pressure.

In some embodiments, the vapor bubbles are allowed to disperse in the liquid working fluid after exiting the outlet of the heat duct. In some embodiments, the heat duct extends to at least the liquid level of the liquid working fluid to confine the vapor bubbles in the heat duct. By limiting and/or preventing the movement of the vapor bubbles out of the heat duct until entering the headspace of the immersion chamber, the density of the working fluid in the heat duct is minimized. With all vapor bubbles created by the boiling of the liquid working fluid by the heat-generating electronic component confined in the heat duct, the relative columnar pressure is maximized. The fluid flow is, therefore, increased.

The heat duct may accelerate the working fluid therethrough by lowering the density of the working fluid in the heat duct. The fluid flow can increase the cooling capacity by flowing cooler liquid working fluid toward the heat-generating electronic component from the immersion bath. In some embodiments, secondary heat-generating electronic components of the server computer or other computing device receive additional cooling from the flow of liquid working fluid drawn into the inlet of the heat duct.

A secondary heat-generating electronic component may be positioned on the server computer or other computing device (e.g., on the same motherboard or other substrate) below the heat duct and/or proximate the heat duct inlet. The heat duct draws liquid working fluid into the inlet, and the induced flow of liquid working fluid proximate the inlet can cool the secondary heat-generating electronic component proximate the inlet.

A heat duct may be placed around or integrated with a heat sink. In some embodiments, the heat sink includes one or more thermal surface features to dissipate heat from the heat-generating electronic component into the working fluid inside the heat duct. The thermal surface features may include fins, rods, heat pipes, vapor chambers, mesh, sponge, surface textures, or any other features that increase the surface area and/or thermal transfer rate of the heat sink and/or heat duct.

In some embodiments, the thermal surface features are located in the heat sink and/or heat duct to longitudinally overlap the heat-generating electronic component. For example, the heat duct may be longer in a longitudinal direction than the heat-generating electronic component, such as a processor. The thermal surface features may be located only in the longitudinal portion of the heat sink and/or heat duct where the heat-generating electronic component is located to receive and transfer heat from the heat-generating electronic component. The heat duct may lack thermal surface features or have less or smaller thermal surface features in the longitudinal portion(s) of the heat duct that does not contact or overlap the heat-generating electronic component. Eliminating or reducing the thermal surface features from the longitudinal portion(s) of the heat duct that does not contact or overlap the heat-generating electronic component can reduce drag on the working fluid and allow for faster fluid flow through the heat duct.

The thermal surface features, in some embodiments, project from an inner surface of the heat duct into interior area of the heat duct to transfer heat to the working fluid therein. The thermal surface features may not contact the opposite inner surface and create a plurality of channels in the heat duct. Having a plurality of channels impedes liquid fluid flow and can increase the risk of dry out in the heat duct.

The heat duct may have any of a variety of cross-sectional shapes (e.g., perpendicular to the longitudinal direction). In some embodiments, the heat duct has a cross-sectional shape that is rectangular, square, triangular, pentagonal, hexagonal, other regular polygonal, curved, round, oval, irregular, or combination thereof. For example, the heat duct may have a cross-sectional shape that is at least partially related to the shape of one or more thermal surface features. In at least one embodiment, the thermal surface feature is a conductive rod (or longitudinal series of rods) that forms an arc fixed to a heat sink, while the heat duct has a cross-sectional shape that is rounded to complementarily follow the curve of the arc.

In at least one embodiment, the thermal surface features contact both a first side of the inner surface and an opposite second side of the inner surface. In such embodiments, the thermal surface features, such as fins, can create isolated channels that inhibit fluid flow in a transverse direction and risk dry out. The thermal surface features may have apertures therein to allow the transverse movement of liquid working fluid through the channel of the heat duct.

The heat duct may include one or more thermal surface features to promote boiling of the liquid working fluid from more than one side of the inner surface. In some embodiments, a vapor chamber is positioned on the inner surface of the heat duct to transfer and/or spread heat from the heat-generating electronic component. The vapor chamber transfers heat from the heat-generating electronic component across the entire inner surface (in cross-section) to equally heat the liquid working fluid and boil the liquid working fluid. In some embodiments, the thermal surface features are positioned on the side of the inner surface opposite the heat-generating electronic component, such that the increased surface area of the thermal surface features results in equal heating of the working fluid from the hotter side proximate the heat-generating electronic component and the cooler side opposite the heat-generating electronic component with the thermal surface features.

Even heating of the liquid working fluid may promote vaporization of the liquid working fluid equally, causing entrainment of the liquid working fluid with the vapor bubbles of the vapor working fluid. Because the movement of (and lower density of) the vapor working fluid in the heat duct establishes the flow through the heat duct, a counter flow of liquid working fluid down the heat duct will adversely impact the cooling capacity of the thermal management system. In some embodiments, the heat duct has enough cross-sectional area to allow fluid flow and prevent dry out while not having too much cross-sectional area to allow counter flow of the liquid working fluid. While promotion of vapor bubbles throughout the cross-sectional area can help prevent counter flow, complementary surface features can also limit the open cross-sectional area of the heat duct and promote entrainment.

In some embodiments, a heat duct has thermal surface features on a top side of the inner surface and on the bottom side (proximate the heat-generating electronic component) of the inner surface. The thermal surface features on opposite or adjacent sides may be complementary to one another to maintain a substantially constant gap between the first thermal surface features on the top side of the inner surface and the second thermal surface features on the bottom side of the inner surface. For example, fins protruding from a top side of the inner surface may be positioned in the spacing between fins protruding from a bottom side of the inner surface.

Thermal management systems, according to the present disclosure, use the change in working fluid density upon boiling to create pressure differentials in the immersion chamber. In some embodiments, a thermal management system uses the pressure differential in the immersion chamber to direct or draw fluid from a particular area or volume of the immersion chamber. For example, a shape of the inlet of the heat duct may be selected to draw liquid working fluid across one or more secondary heat-generating electronic components, as describe herein. For example, a flared or wide inlet may draw liquid working fluid from a larger area across the server computer or other computing device to actively force liquid flow over the secondary heat-generating electronic components. In another example, a flared or wide inlet may draw liquid working fluid into the heat duct, which subsequently narrows in the direction of flow, to accelerate the fluid via the Venturi effect to increase cooling capacity.

In some embodiments, the inlet of the heat duct is located in the immersion chamber to draw liquid working fluid from a particular location in the immersion chamber. For example, the inlet may be directed toward a region of the immersion chamber away from the secondary heat-generating electronic components of the server computer or any other heat-generating electronic components in the immersion chamber to draw in cooler liquid working fluid. In at least one example, the inlet of the heat duct is located proximate a liquid return line outlet. The returning liquid working fluid (e.g., returning from the condenser) may be subcooled below the temperature of the liquid working fluid in the immersion chamber. The liquid working fluid located in the region with the coolest liquid working fluid will provide more efficient cooling to the heat-generating electronic component connected to and/or in thermal conductivity with the heat duct.

While embodiments of thermal management systems have been described with the heat duct oriented generally vertically relative to gravity to allow the vapor bubbles to rise, in some embodiments, at least a portion of the heat duct and heat-generating electronic component may be angled relative to gravity to allow the vapor bubbles to rise away from the heat-generating electronic component in the heat duct.

For example, the server computer motherboard or other substrate may be tilted relative to gravity to position at least a portion of the heat duct vertically above the heat-generating electronic component. As the heat-generating electronic component boils the liquid working fluid in the heat duct, the vapor working fluid will rise in the direction of gravity and away from the surface of the heat-generating electronic component. While this can limit and/or prevent dry out of the component, too large of a tilt angle relative to the direction of gravity can induce a counter flow of liquid working fluid and limit and/or prevent entrainment. In some embodiments, the tilt angle of the heat duct and/or heat-generating electronic component relative to gravity is between 0° and 10°. In some embodiments, the tilt angle of the heat duct and/or heat-generating electronic component relative to gravity is less than 5°. In some embodiments, the tilt angle of the heat duct and/or heat-generating electronic component relative to gravity is less than 2.5°.

The present disclosure relates to systems and methods for cooling heat-generating components of a computer or computing device according to at least the examples provided in the sections below:

[A1] In some embodiments, an immersion cooling thermal management system includes a heat duct thermally coupled to a heat-generating electronic component. The heat duct has an inlet at a first longitudinal end of a channel and an outlet at an opposite second longitudinal end of the channel. The heat-generating electronic component is thermally coupled with the channel longitudinally between the inlet and the outlet. The outlet of the channel is higher than the inlet relative to a direction of gravity.

[A2] In some embodiments, the heat duct of [A1] is polygonal in transverse cross-section.

[A3] In some embodiments, the thermal management system of [A1] or [A2] includes at least one thermal surface feature on an inner surface of the heat duct.

[A4] In some embodiments, the thermal surface feature of [A3] is located on and contacting a bottom side of an inner surface of the heat duct proximate the heat-generating electronic component.

[A5] In some embodiments, the thermal surface feature of [A3] is located on all of an inner surface of the heat duct at at least one longitudinal position in the heat duct.

[A6] In some embodiments, the thermal surface feature of any of [A3] through [A5] is a vapor chamber.

[A7] In some embodiments, the inlet of any of [A1] through [A6] is flared.

[A8] In some embodiments, the outlet of any of [A1] through [A7] is tapered.

[A9] In some embodiments, the heat duct of any of [A1] through [A8] increased in transverse cross-sectional area in the longitudinal direction.

[B1] In some embodiments, a thermal management system includes an immersion chamber, a working fluid positioned in the immersion chamber, a heat-generating component, and a heat duct. The working fluid has a liquid phase and a vapor phase. The heat-generating component is positioned in the liquid phase of the working fluid and fixed to a substrate. The heat duct has an inlet at a first longitudinal end and an outlet at an opposite second longitudinal end. The heat duct is connected to and positioned on the substrate such that the heat-generating electronic component is located longitudinally between the inlet and the outlet to heat a portion of the liquid phase of the working fluid and induce a longitudinal flow of working fluid through the heat duct.

[B2] In some embodiments, the working fluid of [B1] has a boiling temperature between 50° C. and 90° C.

[B3] In some embodiments, the heat-generating component of [B1] or [B2] has a peak operating power of at least 400 Watts.

[B4] In some embodiments, an operating temperature of the heat-generating components is at least 0.10° C. greater than the boiling temperature of the working fluid.

[B5] In some embodiments, a density of the liquid phase of any of [B1] through [B4] is at least 100 times greater or more than a density of the vapor phase.

[C1] In some embodiments, a thermal management system includes an immersion chamber, a working fluid positioned in the immersion chamber, a first heat-generating electronic component, a second heat-generating electronic component, and a heat duct. The working fluid has a liquid phase and a vapor phase, and the vapor phase defines a headspace above the liquid phase. The first heat-generating component is positioned in the liquid phase of the working fluid and fixed to a substrate. The heat duct has an inlet at a first longitudinal end and an outlet at an opposite second longitudinal end. The heat duct is connected to and positioned on the substrate such that the first heat-generating electronic component is located longitudinally between the inlet and the outlet to heat a portion of the liquid phase of the working fluid and induce a longitudinal flow of working fluid through the heat duct. The second heat-generating component is positioned in the liquid phase of the working fluid and fixed to the substrate outside of the heat duct and proximate the inlet, such that the longitudinal flow of working fluid cools the second heat-generating electronic component.

[C2] In some embodiments, the outlet of [C1] is positioned in the headspace.

[C3] In some embodiments, the first heat-generating electronic component and the second heat-generating electronic component of [C1] or [C2] are part of a computing device, and the inlet is oriented away from the computing device.

[C4] In some embodiments, the second heat-generating electronic component is positioned in the heat duct.

[C5] In some embodiments, the thermal management system of any of [C1] through [C4] includes a liquid return line from a condenser, and the inlet is oriented toward an outlet of the liquid return line.

[C6] In some embodiments, the substrate and heat duct of any of [C1] through [C5] are oriented at a tilt angle to a direction of gravity that is less than 10°.

The articles “a,” “an,” and “the” are intended to mean that there are one or more of the elements in the preceding descriptions. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

It should be understood that any directions or reference frames in the preceding description are merely relative directions or movements. For example, any references to “front” and “back” or “top” and “bottom” or “left” and “right” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. An immersion cooling thermal management system comprising:
a heat duct with an inlet at a first longitudinal end of a channel and an outlet at an opposite second longitudinal end of the channel,
a heat-generating electronic component that is thermally coupled with the channel longitudinally between the inlet and the outlet;
wherein the heat duct is thermally coupled to the heat-generating component and the outlet is higher than the inlet relative to a direction of gravity.

2. The thermal management system of claim 1, wherein the heat duct is polygonal in transverse cross-section.

3. The thermal management system of claim 1, further comprising at least one thermal surface feature on an inner surface of the heat duct.

4. The thermal management system of claim 3, wherein the at least one thermal surface feature is located on and contacting a bottom side of an inner surface of the heat duct proximate the heat-generating electronic component.

5. The thermal management system of claim 3, wherein the at least one thermal surface feature is located on all of the inner surface of the heat duct at at least one longitudinal position in the heat duct.

6. The thermal management system of claim 3, wherein the at least one thermal surface feature is a vapor chamber.

7. The thermal management system of claim 1, wherein the inlet is flared.

8. The thermal management system of claim 1, wherein the outlet is tapered.

9. The thermal management system of claim 1, wherein the heat duct increases in transverse cross-sectional area in the longitudinal direction.

10. A thermal management system comprising:
an immersion chamber;
a working fluid positioned in the immersion chamber, the working fluid having a liquid phase and a vapor phase;
a heat-generating electronic component positioned in the liquid phase of the working fluid and fixed to a substrate; and
a heat duct with an inlet at a first longitudinal end and an outlet at an opposite second longitudinal end, wherein the heat duct is connected to and positioned on the substrate such that the heat-generating electronic component is located longitudinally between the inlet and the outlet to heat a portion of the liquid phase of the working fluid and induce a longitudinal flow of working fluid through the heat duct.

11. The thermal management system of claim 10, wherein a boiling temperature of the working fluid is between 50° C. and 90° C.

12. The thermal management system of claim 10, wherein the heat-generating component has a peak operating power of at least 400 Watts.

13. The thermal management system of claim 10, wherein an operating temperature of the heat-generating electronic component is at least 0.10° C. greater than the boiling temperature of the working fluid.

14. The thermal management system of claim 10, wherein a density of the liquid phase is at least 100 times greater than a density of the vapor phase.

15. A thermal management system comprising:
an immersion chamber;
a working fluid positioned in the immersion chamber, the working fluid having a liquid phase and a vapor phase, wherein the vapor phase defines a headspace above the liquid phase;
a first heat-generating electronic component positioned in the liquid phase of the working fluid and fixed to a substrate; and
a heat duct with an inlet at a first longitudinal end and an outlet at an opposite second longitudinal end, wherein the heat duct is connected to and positioned on the substrate such that the first heat-generating electronic component is located in the heat duct longitudinally between the inlet and the outlet to heat a portion of the liquid phase of the working fluid and induce a longitudinal flow of working fluid through the heat duct; and
a second heat-generating electronic component positioned in the liquid phase of the working fluid and fixed to the substrate and proximate the inlet, such that the longitudinal flow of working fluid cools the second heat-generating electronic component.

16. The thermal management system of claim 15, wherein the outlet is positioned in the headspace.

17. The thermal management system of claim 15, wherein the first heat-generating electronic component and the second heat-generating electronic component are part of a computing device, and the inlet is oriented away from the computing device.

18. The thermal management system of claim 15, wherein the second heat-generating electronic component is positioned in the heat duct.

19. The thermal management system of claim 15, further comprising a liquid return line from a condenser, wherein the inlet is oriented toward an outlet of the liquid return line.

20. The thermal management system of claim 15, wherein the substrate and heat duct are oriented at a tilt angle to a direction of gravity that is less than 10°.
